(19) United States
(12) Patent Application Publication
(10) Pub. No.: US 2009/0180213 A1
(43) Pub. Date: Jul. 16, 2009

(54) MAGNETIC RECORDING MEDIUM, METHOD FOR PRODUCTION THEREOF, AND MAGNETIC RECORDING AND REPRODUCING DRIVE

(75) Inventors: Masato Fukushima, Chiba (JP); Akira Sakawaki, Chiba (JP); Yasumasa Sasaki, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/280,073

(22) PCT Filed: Feb. 19, 2007
(86) PCT No.: PCT/JP2007/053449

§ 371 Date: Dec. 5, 2008

Related U.S. Application Data
(60) Provisional application No. 60/776,732, filed on Feb. 27, 2006.

(30) Foreign Application Priority Data
Feb. 21, 2006 (JP) 2006-044295

(51) Int. Cl. G11B 21/02; G11B 5/82; C23C 14/04

(52) U.S. Cl. 360/75; 360/135; 427/526; G9B/5.293; G9B/21.003

(57) ABSTRACT

A discrete track-type magnetic recording medium (30) includes a nonmagnetic substrate (1), a magnetic recording track and a servo signal pattern that are provided on at least one side of the nonmagnetic substrate and a part (4) nonmagnetized through implantation (7) of ions from above a mask (6) having a shape of a pattern expected to be separated for physically separating the magnetic recording track and the servo signal pattern. A magnetic recording and reproducing device includes the magnetic recording medium (30), a driving part (26) serving to drive the magnetic recording medium in a direction of recording, a magnetic head (27) composed of a recording part and a reproducing part, means (28) to impart motion to the magnetic head relative to the magnetic recording medium and recording and reproducing signal processing means (29) for entering a signal into the magnetic head and reproducing an output signal from the magnetic head.

### CROSS REFERENCE TO RELATED APPLICATIONS

This application is an application filed under 35 U.S.C. §111(a) claiming the benefit pursuant to 35 U.S.C. §119(e)(1) of the filing dates of Provisional Application No. 60/776,732 filed Feb. 27, 2006 and Japanese Patent Applications No. 2006-044295 filed Feb. 21, 2006 and No. 2006-111833 filed Apr. 14, 2006 pursuant to 36 U.S.C. §111(b).

### TECHNICAL FIELD

This invention relates to a magnetic recording medium for use as in a hard disk drive, a method for the production thereof, and a magnetic recording and reproducing device.

### BACKGROUND ART

In recent years, as magnetic recording devices, such as magnetic disk drives, flexible disk drives and magnetic tape drives, have immensely expanded their ranges of utility and gained in significance, efforts have been directed toward enabling the magnetic recording media used in these devices to be prominently improved in recording density. Particularly, the increase in surface recording density has been further growing in ardency since the introduction of the Magneto Resistive (MR) head and the Partial Response Maximum Likelihood (PRML) technique. Owing to the further introduction of the Giant-Magneto Resistive (GMR) head and the Tunneling Magnet Resistive (TMR) head in recent years, the increase is continuing at a pace of about 100% per year. These magnetic recording media are being urged to attain a still higher recording density in future and their magnetic recording layers to accomplish addition to coercive force, Signal-to-Noise Ratio (SNR) and resolution. Recent years have been witnessing efforts that are being continued with the object of enhancing the linear recording density and adding to the surface recording density by increasing the track density as well.

In the latest magnetic recording devices, the track density has reached 110 kTPI. As the track density is further increased, it tends to entail such problems as causing interference between the parts of information magnetically recorded in adjacent tracks and inducing the magnetization transition region in the borderline region to constitute a noise source and impair the SNR. This fact hinders the enhancement of the recording density because it immediately results in lowering the bit error rate.

For the sake of increasing the surface recording density, it is necessary that the individual recording bits on the magnetic recording medium be formed in as minute a size as possible and enabled to secure as large saturated magnetization and magnetic film thickness as permissible. As the recording bits further decrease in size, however, they tend to entail such problems as lessening the minimum volume of magnetization per bit and inducing extinction of recorded data through the magnetization reversal caused by thermal fluctuation.

Further, since the track pitch grows small, the magnetic recording device necessitates a track servo technique of extremely high accuracy and, at the same time, generally needs adoption of the method of executing the recording in a large width and executing the reproducing in a smaller width than during the recording with a view to eliminating the influence from the adjacent tracks to the fullest possible extent Notwithstanding that this method is capable of suppressing the influence between the adjacent tracks to a minimum, it entails such problems as rendering sufficient acquisition of the output of reproduction difficult and consequently incurring difficulty in securing a sufficient SNR.

As one means to cope with the problem of thermal fluctuation and accomplish acquisition of a due SNR or a sufficient output, an attempt to enhance the track density by forming irregularities along the tracks on the surface of the recording medium and consequently physically separating mutually the adjacent tracks is now under way. This technique will be referred to as a “discrete track technique” and the magnetic recording media that are produced by this technique will be referred to as “discrete track media” herein below.

As one example of the discrete track medium, a magnetic recording medium that is formed on a nonmagnetic substrate bestowed on the surface thereof with irregular patterns and enabled to acquire physically separated magnetic recording track and servo signal pattern has been known (refer, for example, to JP-A 2004-164692).

This magnetic recording medium has a ferromagnetic layer formed on the surface of a substrate possessing a plurality of irregularities on the surface thereof via a soft magnetic layer and has a protecting film formed on the surface of the ferromagnetic layer. This magnetic recording medium has formed in the convexed regions thereof magnetic recording regions magnetically divided from the environments.

According to this magnetic recording medium, it is held that a high-density magnetic recording medium issuing no great noise can be formed because the fact that the occurrence of magnetic walls in a soft magnetic layer can be suppressed results in preventing the influence of thermal fluctuation from readily appearing and allowing extinction of interference between the adjacent signals.

The discrete track technique is known in two kinds, i.e. a method which forms a track subsequent to forming a magnetic recording medium consisting of a number of stacked thin films and a method which forms a thin-film magnetic recording medium either directly on the surface of a substrate or subsequent to forming irregular patterns on a thin-film layer ready for the formation of a track (refer, for example, to JP-A 2004-178793 and JP-A 2004-178794). The former method, often called a magnetic layer processing-type method, is at a disadvantage in suffering the medium to be readily contaminated during the course of production and greatly complicating the process of production as well because it requires the physical processing of surfaces to be carried out subsequent to the formation of the medium. The latter method, often called an emboss processing-type method, though not inducing ready contamination during the course of production, is at a disadvantage in disabling stabilization of the posture and the height of floatation of the recording and reproducing head adapted to execute recording and reproducing while floating on the medium because the irregular shape formed on the substrate is fated to continue existence on the film to be formed.

The emboss processing-type method of production enables no easy realization of a flat surface because the irregular shape formed on the substrate is overlaid with the magnetic layer and the protecting layer and is consequently suffered to continue the existence thereof on the surface to be completed.

On the other hand, the discrete track-type magnetic recording medium by the magnetic layer processing-type method adopts a procedure of forming the magnetic layer used for recording on the surface of the substrate and subsequently forming a magnetic pattern and, therefore, acquires a structure that results from executing pattern formation by the imprinting method utilized as for semiconductors, subsequently dry-etching the part fated to form a nonmagnetic part, thereafter embedding SiO₂ or a carbon-based nonmagnetic material, subjecting the resultant surface to a planarizing treatment, further coating the surface with a protecting film layer, and forming a lubricating layer thereon. This magnetic etching-type discrete track medium complicates the process of production and not only forms a cause for contamination but also fails to realize a flat surface.

Generally, the magnetic recording medium of such a structure as this enables enlarging the output and input signals through the head and heightening the recording density as well because the distance from the head to the magnetic layer decreases in accordance as the protecting film layer becomes thin. The pit density in the track is decided by the height of floatation of the head running on the surface of the protecting film layer of an irregular shape. How the floatation of the head is stably retained, therefore, constitutes an important task for the sake of accomplishing a high recording density. The irregular pattern, therefore, is required to be capable of allowing the floatation of the head to be stably retained, enabling the head to approximate as closely to the magnetic layer as possible, and moreover preventing mutual interference of signals on the adjacent tracks.

A technique for producing a discrete track medium that entails scarcely the risk of causing contamination during the course of production and enables formation of a flat surface, however, has not been proposed to date.

This invention is directed, in the magnetic recording device confronting technical difficulty in consequence of the increase in the track density, toward immensely increasing the track density and consequently increasing the surface recording density while ensuring acquisition of higher recording and reproducing properties than ever. Particularly in the discrete track-type magnetic recording medium adapted to execute formation of a pattern subsequent to having a magnetic layer formed on a substrate, this invention is directed toward providing a method for production that exceptionally simplifies the process of production as compared with the conventional process of the magnetic layer processing-type by depriving this conventional process of a step for removing the magnetic layer and a patterning step resorting to application of resist and sparingly entails the risk of causing contamination and a discrete track-type magnetic recording medium that excels in the head-floating property and proves to be useful.

With a view to solving the problems mentioned above, this invention provides a discrete track medium and a magnetic recording device.

### DISCLOSURE OF THE INVENTION

The present invention provides as the first aspect thereof a discrete track-type magnetic recording medium comprising a nonmagnetic substrate, a magnetic recording track and a servo signal pattern which are provided on at least one side of the nonmagnetic substrate and a part nonmagnetized through implantation of ions from above a mask having a shape of a pattern expected to be separated for physically separating the magnetic recording track and the servo signal pattern.

The second aspect of the invention provides the magnetic recording medium according to the first aspect, wherein the magnetic recording track is a vertical magnetic recording track.

The present invention also provides as the third aspect thereof a method for the production of a discrete track-type magnetic recording medium provided on at least one side of a nonmagnetic substrate with physically separated magnetic recording track and servo signal pattern, the method comprising the step of implanting ions from above a mask having a shape of a pattern expected to be separated, thereby forming a part nonmagnetized for physically separating the magnetic recording track and the servo signal pattern.

The present invention further provides as the fourth aspect thereof a magnetic recording and reproducing device comprising in combination the magnetic recording medium according to the first or second aspect, a driving part serving to drive the magnetic recording medium in a direction of recording, a magnetic head composed of a recording part and a reproducing part, means to impart motion to the magnetic head relative to the magnetic recording medium and recording and reproducing signal processing means for entering a signal into the magnetic head and reproducing an output signal from the magnetic head.

This invention, in a discrete track magnetic recording medium executing formation of a pattern subsequent to having a magnetic layer disposed as a film on a nonmagnetic substrate, enables provision of a magnetic recording medium that permits securing stability of head floatation, possesses an excellent track separating property, avoids succumbing to the influence of signal interference between the adjacent tracks, and excels in a high recording density property. Further, since this invention permits omission of a dry etching step serving to remove the magnetic layer processing-type magnetic layer hitherto held to entail an extremely complicated process of production, a resist-applying step required for the formation of a pattern and a step for removing the resist after use, it is capable of not merely contributing greatly to the enhancement of productivity but also avoiding the occurrence of particles and enabling production of an excellent magnetic recording medium.

The magnetic recording and reproducing device that is produced by this invention, owing to the use of the magnetic recording medium contemplated by this invention, excels in the head-floating property and in the track-separating ability and, owing to the avoidance of the influence of signal interference between the adjacent tracks, excels in the high recording density property.

### BRIEF DESCRIPTION OF DRAWINGS

FIG. 1 is a cross section showing the structure of a magnetic recording medium of this invention.

FIG. 2 is an explanatory view showing the configuration of a magnetic recording and reproducing device of this invention.

### BEST MODE OF EMBODYING THE INVENTION

First, the cross-sectional structure of the discrete-type magnetic recording medium of this invention will be described.

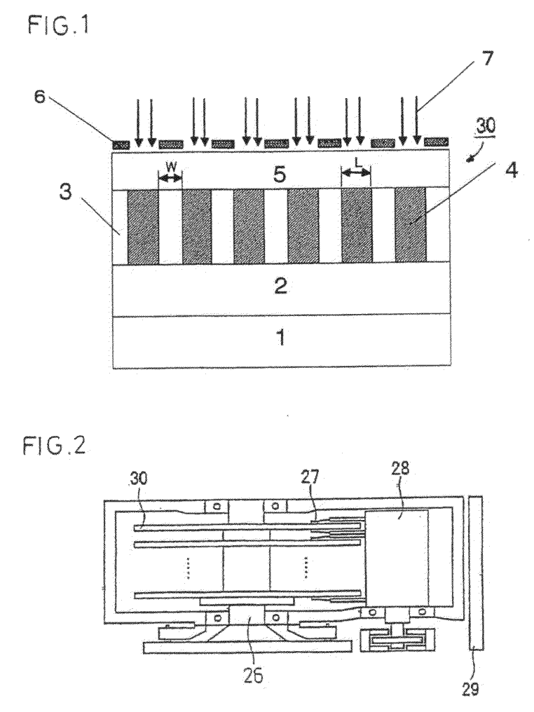

FIG. 1 depicts the cross-sectional structure of the discrete-type magnetic recording medium of this invention, inclusive of the image of a mask and implantation of ions. A magnetic recording medium 30 of this invention possesses a structure resulting from forming on the first surface of a nonmagnetic substrate 1 a soft magnetic layer and an intermediate layer 2, a magnetic layer 3 having a pattern magnetically formed thereon, and an unmagnetized layer 4 and a protecting-film layer 5 and further forming on the outermost surface a lubricating film omitted from illustration. A mask 6 having a prescribed pattern formed in advance therein is set perpendicularly to implantation 7 of ions and in parallel to the magnetic recording medium. Though the mask for use in this invention has adopted quartz as its material, any material, such as soda lime glass or Si wafer, which is capable of intercepting ions and consequently forming a prescribed pattern may be used for the mask.

For the purpose of heightening recording density, the magnetic layer 3 possessing a magnetic pattern prefers to have a magnet part width W of 100 hid or less and a nonmagnetic part width L of 200 nm or less. The track pitch P (= W+L), therefore, is decreased to the fullest possible extent in the range of 300 nm or less with the object of heightening the recording density.

As the nonmagnetic substrate for use in this invention, any of the nonmagnetic substrates, such as Al alloy substrates made of Al—Mg alloys having Al as a main component, substrates made of ordinary soda glass, aluminosilicate-based glass, glass ceramics and substrates made of silicon, titanium, ceramics and various resins may be optionally used. Among other materials enumerated above, Al alloy substrates, glass substrates made of glass ceramics and silicon substrates are used particularly favorably. The substrate thus selected prefers to have an average surface roughness (Ra) of 1 nm or less, preferably 0.5 nm or less, and particularly preferably 0.1 nm or less.

The magnetic layer to be formed on the first surface of the nonmagnetic substrate of the quality mentioned above may be an in-plane magnetic recording layer or a vertical magnetic recording layer. For the purpose of realizing high recording density, however, it prefers to be a vertical magnetic recording layer. Preferably, the magnetic recording layer is formed of an alloy formed mainly of Co as a principal component.

As the magnetic recording layer for use in the in-plane magnetic recording medium, for example, a stacked structure that is composed of a nonmagnetic CrMo under layer and a ferromagnetic CoCrPtAa magnetic layer can be utilized.

As the magnetic recording layer for use in the vertical magnetic recording medium, a stacked body that is composed of a backing layer made of soft magnetic FeCo alloy (such as FeCoB, FeCoSiB, FeCoZr, FeCoZrB, FeCoZrBCu or the like), FeTa alloy (such as FeTaN, FeTaC or the like) or Co alloy (such as CoTaZr, CoZrNB, CoB or the like), an orientation-controlling film made of Pt, Pd, NiCr, NiFeCr or the like, optionally an intermediate layer made of Ru or the like, and a magnetic layer made of a 60Co-15Cr-15Pt alloy or a 70Co-5Cr-15Pt-10SiO₂ alloy may be used.

The thickness of the magnetic recording layer is 3 nm or more and 20 nm or less, preferably 5 nm or more and 15 nm or less. The magnetic recording layer needs only to be so formed in conformity with the kind of magnetic alloy used and the structure of stacked body that the head may be enabled to gain sufficient output and input. The magnetic layer needs to have a film thickness of a certain degree or more for the purpose of obtaining an output of a prescribed degree or more during the course of reproduction. Meanwhile, the magnetic layer must be set at an optimum film thickness in view of the fact that the various parameters representing the recording and reproducing properties are generally deteriorated in proportion as the output increases.

Generally, the magnetic recording layer is formed as a thin film by the sputtering method.

The protecting-film layer 5 is formed on the first surface of the magnetic recording layer. For the protecting-film layer, commonly used protective-film layer materials, such as carbonaceous substances including carbon (C), hydrogenated carbon (HₓC), carbon nitride (CN), amorphous carbon, silicon carbide (SiC) and the like, SiO₂, Zr₂O₃, TiN and the like are available. The protecting-film layer may be formed of two or more layers.

The film thickness of the protecting-film layer 3 must be less than 10 nm. If the film thickness of the protecting-film layer exceeds 10 nm, the excess will result in unduly enlarging the distance between the head and the magnetic layer and preventing the input and output signals from acquiring sufficient intensity. Generally, the protecting-film layer is formed by the sputtering method or the CVD method.

The protecting-film layer prefers to have the lubricating layer formed thereon. As the lubricating agent for use in the lubricating layer, fluorine-based lubricating agents, hydrocarbon-based lubricating agents, and mixtures thereof may be available, for example. The lubricating layer is generally formed in a thickness of 1 to 4 nm.

Next, the method for producing the discrete-type magnetic recording medium of this invention will be specifically described below.

The process for producing a magnetic recording medium normally begins with a work of cleaning and drying a substrate. This invention also prefers to perform the work of cleaning and drying the substrate prior to forming the magnetic-film layer from the viewpoint of ensuring adherence between the component layers. The substrate does not need to have its size particularly restricted.

This invention has a soft magnetic layer of FeCoB, an intermediate layer of Ru, a magnetic layer of a 70Co-5Cr-15Pt-10SiO₂ alloy and a protecting-film layer of carbon formed on the first surface of the substrate.

Subsequently, the substrate is set in the chamber of an ion-implanting device and the magnetic layer is disposed directly above the substrate, both perpendicularly to the direction of ion implantation, and the device is actuated to inject into the chamber ions capable of unmagnetizing the magnetic layer. This invention contemplates using Si as the source of the ions.

For the sake of implanting atoms with the ion-implanting device, a commercially available ion-implanting device is utilized for effecting the implantation in the magnetic layer. Though Si, In, B, P, C, F and the like are available for the implantation of ions, the ions do not need to be particularly restricted by their kinds or mixtures. They are solely required to be implanted and utilized for the extinction of magnetism. This invention, in effecting the implantation of atoms, contemplates causing the implantation made in the direction of depth of the magnetic layer to reach a region between the central part of the depth and a farther depth and consequently enabling the atoms to be distributed to a certain degree in the direction of depth of the magnetic layer. This invention does not particularly limit the depth of implantation because it aims to implant atoms into the magnetic layer and unmagnetize the pertinent part thereof. The depth of the implantation of atoms is properly decided by the magnitude of the acceleration voltage of the ion-implanting device in use.

For the formation of the component layers of the magnetic recording medium excepting the protecting-film layer 3, the RF sputtering method, the DC sputtering method and the like which are generally used as means to form a film are available.

On the other hand, the formation of the protecting-film layer generally resorts to the transformation of diamond like carbon transformed into a thin film as by means of P-CVD. This method, however, is not an exclusive means.

Next, the structure of the magnetic recording and reproducing device of this invention is shown in FIG. 2. The magnetic recording and reproducing device of this invention is provided with the magnetic recording medium 30 of this invention, a medium-driving part 26 for driving the medium in the direction of recording, a magnetic head 27 consisting of a recording part and a regenerating part, a head-driving part 28 for moving the magnetic head 27 relative to the magnetic recording medium 30 and a recording and reproducing signal system 29 combining recording and reproducing signal-processing means for entering a signal into the magnetic head 27 and regenerating a signal produced from the magnetic head 27. By combining these components, it is made possible to configure a magnetic recording and reproducing device possessing a high recording density. Owing to the physically discrete fabrication of the recording track of the magnetic recording medium, this invention enables the regenerating head and the recording head to be actuated in nearly the same widths, whereas the practice of eliminating the influence of the magnetization transition region of the track edge part by giving the regenerating head a smaller width than the recording head has prevailed to date. Consequently, it is made possible to obtain a satisfactory regeneration output and a high SNR.

Further by forming the regenerating part of the magnetic head with a GMR head or TMR head, it is made possible to obtain satisfactory signal strength even at a high recording density and realize a magnetic recording device possessing a high recording density. The recording density can be further enhanced by incorporating in the combination a signal processing circuit conforming to the maximum likelihood decoding method. A satisfactory SNR can be obtained even in the case of performing a recording and reproducing operation at a track density of 100 k tracks or more per inch, a linear recording density of 1000 k bits or more per inch, and a recording density of 100 G pits or more per square inch.

### Comparative Example 1

A vacuum chamber having an HD-oriented glass substrate set therein was evacuated in advance to a vacuum of 1.0×10⁻⁵ Pa or less. The glass substrate used herein was made of glass ceramic using Li₂Si₂O₅, Al₂O₃K₂O, Al₂O₃—K₂O, MgO—P₂O₅ and Sb₂O₃—ZnO as components. It measured 65 mm in outside diameter and 20 mm in inside diameter and had an average surface roughness (Ra) of 2 Å.

On the glass substrate, an SiO₂ film was formed as a pre-emboss layer in a thickness of 200 nm by an ordinary RF sputtering method.

Next, the resultant coated substrate was imprinted by the use of stampers made of Ni and prepared in advance. The stampers had a track pitch of 100 nm. The grooves were invariably adjusted to a depth of 20 nm. The imprinting was implemented by using stampers of relevant designs.

Then, the SiO₂ layer was etched by means of ion-beam etching. The thin part of the SiO₂ layer was etched to a depth reaching the substrate, with the result that a convexo-concave pattern conforming to the irregularities formed by the stampers was formed on the first surface of the substrate.

On the first surface of the substrate, a soft magnetic layer of FeCoB, an intermediate layer of Ru and a magnetic layer of a 70Co-5Cr-15Pt-10SiO₂ alloy were stacked by the DC sputtering method and a C (carbon) protecting-film layer and a fluorine-based lubricating film were further stacked by the P-CVD method, sequentially in the order mentioned.

The FeCoB soft magnetic layer measured 600 Å, the Ru intermediate layer 100 Å, the magnetic layer 150 Å and the C (carbon) protecting-film layer an average of 4 nm, respectively, in film thickness. This sample was obtained as an example of the embossed product of Comparative Example 1.

### Comparative Example 2

A vacuum chamber having an HD-oriented glass substrate set therein was evacuated in advance to a vacuum of 1.0×10⁻⁵ Pa or less. The glass substrate used herein was made of glass ceramic using Li₂Si₂O₅, Al₂O₃—K₂O, Al₂O₃—K₂O, MgO—P₂O₅ and Sb₂O₃—ZnO as components. It measured 65 mm in outside diameter and 20 mm in inside diameter and had an average surface roughness (Ra) of 2 Å.

On the glass substrate, a soft magnetic layer of FeCoB, an intermediate layer of Ru and a magnetic layer of a 70Co-5Cr-15Pt-10SiO₂ alloy were stacked by the DC sputtering method and a C (carbon) protecting-film layer and a fluorine-based lubricating film were further stacked by the P-CVD method, sequentially in the order mentioned. The FeCoB soft magnetic layer measured 600 Å, the Ru intermediate layer 100 Å, the magnetic layer 150 Å and the C (carbon) protecting-film layer an average of 4 nm, respectively, in film thickness. Subsequently, the magnetic layer was subjected to a fabricating treatment to form a magnetic pattern thereon. To be specific, after a resist of thermosetting resin was applied to form irregularities conforming to a prescribed pattern, the concaved parts of the magnetic layer were removed by ion milling in the vacuum device, the remaining convexed parts of the resist were peeled, and a film of carbon was formed with the object of embedding the removed parts of the magnetic layer. Thereafter, carbon was deposited in the form of a film 4 nm in thickness by the P-CVD method to give rise to a lubricating member. The resultant surface was planarized by means of ion-beam etching. The sample thus obtained was placed in a vacuum chamber evacuated in advance to a vacuum of 1×10⁻⁴ Pa and Ar gas was introduced in the chamber till the partial pressure reached 5 Pa. The surface of the sample was etched by applying a RF voltage of 300 W to the sample. This sample was obtained as an example of the fabricated product of magnetic layer of Comparative Example 2.

In the embedding process, a nonmagnetic material is used as the object of embodiment. In the manufacture of the present sample, SiO₂ was used. The production of the film adopted the sputtering technique.

Incidentally, the pattern to be formed subsequent to the application of the resist may be in the shape of the tracks each consisting of a concavity and a convexity that are formed on the first surface of the protecting-film layer by directly adhering a given stamper to the protecting film formed subsequent to the substrate or the magnetic layer and pressing the stamper under high pressure. Alternatively, the pattern may comprise convexities and concavities that are formed by utilizing a thermosetting resin, a UV setting resin or the like.

As the stamper for use in the process, a metallic plate having a fine track pattern formed by a method, such as electron beam imaging technique, may be used. The material of the stamper is required to possess hardness and durability capable of withstanding the impact of the process. Ni, for example, can be used. The material is only required to meet the purpose mentioned above and the kind thereof is irrelevant. The stamper has formed thereon such servo signal patterns as a burst pattern, a gray cord pattern and a preamble pattern besides the tracks for recording ordinary data.

On the occasion of removing the resist, the resist on the surface and part of the protecting-film layer are removed by using a technique, such as dry etching, reactive ion etching or ion milling. In consequence of these treatments, the magnetic layer and part of the protecting-film layer on which the magnetic pattern has been formed remain. By selecting the conditions, the protecting-film layer may be completely removed and the magnetic layer having the pattern formed thereon may be allowed alone to remain.

### Example 1

A vacuum chamber having an HD-oriented glass substrate set therein similarly to Comparative Example 2 was evacuated in advance to a vacuum of 1.0×10⁻⁵ Pa or less. The glass substrate used herein was a glass ceramic that was composed of Li₂Si₂O₅, Al₂O₃—K₂O, MgO—P₂O₅ and Sb₂O₃—ZnO. It measured 65 mm in outside diameter and 20 mm in inside diameter and had an average surface roughness (Ra) of 2 Å.

On the glass substrate, a soft magnetic layer of FeCoB, an intermediate layer of Ru and a magnetic layer of a 70Co-5Cr-15Pt-10SiO₂ alloy were stacked by the DC sputtering method and a C (carbon) protecting-film layer and a fluorine-based lubricating film were further stacked by the P-CVD method, sequentially in the order mentioned. The FeCoB soft magnetic layer measured 600 Å, the Ru intermediate layer 100 Å, the magnetic layer 150 Å and the C (carbon) protecting-film layer an average of 4 nm, respectively, in film thickness.

Thereafter, a magnetic pattern was formed by the technique of this invention. To be specific, a mask wherein a pattern expected to be formed had been incited in advance was disposed on the glass substrate having component layers stacked up to the protecting-film layer and all these are set in an ion-implanting device and then exposed to Si ions, with the result that a nonmagnetic pattern was formed in the expected shape. Thereafter, a lubricant was applied to complete production of a magnetic recording medium. The sample thus obtained served as an example of the product of Example 1. In the ion implantation, the accelerating voltage was fixed at 28 keV and the implanting dose at 5×10¹⁶/cm².

The samples of Example 1 and Comparative Examples 1 and 2 were evaluated for electromagnetic conversion characteristic by the use of a spin stand. In this evaluation, a vertical recording head was used for recording and a TuMR head for reading. The samples after having recorded a signal of 750kFCI were tested for SNR value and 3T-squash. It was found that the sample of Example 1 was substantially improved in RW properties, such as SNR and 3T-squash, as compared with the samples of Comparative Examples 1 and 2. It is inferred that this improvement resulted from stabilizing the head floatation property and consequently enabling RW to proceed at a prescribed height of floatation. On account of the confirmation of the RW properties, such as SNR and ST-squash, it was also confirmed that the sample of Example 1 allowed distinct separation of the adjacent tracks with a nonmagnetic part and as well, in accordance with this invention, enabled a magnetic pattern comprising magnetic parts and nonmagnetic parts to be formed in the magnetic layer part thereof in conformity with a pattern in the prescribed shape.

After completion of the determination of the electromagnetic conversion characteristic, the samples of Example 1 and Comparative Examples 1 and 2 were tested for surface roughness by the use of an AFM. The nonmagnetic substrates produced in Example 1 and Comparative Examples 1 and 2 for use in a vertical recording medium were evaluated for roughness (Ra) in a visual field of 10 μm with an AFM made by Digital Instruments Corp. The evaluation used a resolution of 256×256 tapping mode and a sweep rate of 1 μm/sec. The results of the evaluation are shown in Table 1 below. The sample of Example 1 showed a markedly low magnitude of surface roughness as compared with the samples of Comparative Examples 1 and 2. It is inferred that this improvement resulted in stabilizing the head floatation.

The samples of Example 1 and Comparative Examples 1 and 2 were evaluated for glide avalanche property. The evaluation was performed in a device made by Sony/Tektronix Corp. and sold under the product code of “DS4100” by the use of a 50% slider head made by Glideright Hardware Corp. The results of the evaluation are shown in Table 1 below. It is clear that Example 1 excelled Comparative Examples 1 and 2 in head-floating property because of low glide avalanche.

This comparison of Example 1 and Comparative Examples 1 and 2 has made it clear that this invention enables convenient production of a discrete medium exhibiting sufficiently low surface roughness and producing stable head floatation by implanting ions from above a mask of the shape of a pattern needed to be separated and consequently unmagnetizing the magnetic layer in the needed shape. As this comparison of Example 1 and the Comparative Examples 1 and 2 clearly shows, the production so implemented as to lower the surface roughness to the fullest possible extent forms an important factor for the sake of stabilizing the head floatation. This invention prefers to fix surface roughness at Ra≦2 nm and more favorably at Ra≦1.5 nm. It is evident that this invention serves as an effective means for separating patterned nonmagnetic and magnetic layers and further for producing a patterned medium aimed at, at still higher recording density than the discrete method.

TABLE 1

| | | Amount of | | | | | |
|---|---|---|---|---|---|---|---|
| | Kind of | ions | Accelerated | | 3T | | Glide |
| | ions | implanted | voltage | SNR | squash | Ra | avalanche |
| | implanted | (atom/cm²) | (keV) | (dB) | (%) | (nm) | (nm) |
| Ex. 1 | Si | 5 × e16 | 28 | 13.2 | 85.3 | 0.5 | 5.5 |
| Comp. Ex. 1 | None | None | | 6.5 | 54.3 | 8.0 | 12.1 |
| Comp. Ex. 2 | None | None | | 10.5 | 69.8 | 2.7 | 9.5 |

### INDUSTRIAL APPLICABILITY

The magnetic recording medium of the present invention permits securing stability of head floatation, possesses an excellent track separating property, excels in a high recording density property, can simplify the process of production and is capable of not only contributing greatly to the enhancement of productivity but also avoiding the occurrence of particles.

1. A discrete track-type magnetic recording medium comprising:
a nonmagnetic substrate;
a magnetic recording track and a servo signal pattern provided on at least one side of the nonmagnetic substrate; and
a part nonmagnetized through implantation of ions from above a mask having a shape of a pattern expected to be separated for physically separating the magnetic recording track and the servo signal pattern.

2. A magnetic recording medium according to claim 1, wherein the magnetic recording track is a vertical magnetic recording track.

3. A method for the production of a discrete track-type magnetic recording medium provided on at least one side of a nonmagnetic substrate with physically separated magnetic recording track and servo signal patter, the method comprising the step of implanting ions from above a mask having a shape of a pattern expected to be separated, thereby forming a part nonmagnetized for physically separating the magnetic recording track and the servo signal pattern.

4. A magnetic recording and reproducing device comprising in combination:
the magnetic recording medium according to claim 1;
a driving part serving to drive the magnetic recording medium in a direction of recording;
a magnetic head composed of a recording part and a reproducing part;
means to impart motion to the magnetic head relative to the magnetic recording medium; and
recording and reproducing signal processing means for entering a signal into the magnetic head and reproducing an output signal from the magnetic head.

5. A magnetic recording and reproducing device comprising in combination:
the magnetic recording medium according to claim 2;
a driving part serving to drive the magnetic recording medium in a direction of recording;
a magnetic head composed of a recording part and a reproducing part;
means to impart motion to the magnetic head relative to the magnetic recording medium; and
recording and reproducing signal processing means for entering a signal into the magnetic head and reproducing an output signal from the magnetic head.
